(19) United States
(12) Patent Application Publication
(10) Pub. No.: US 2007/0047347 A1
(43) Pub. Date: Mar. 1, 2007

(54) Semiconductor memory devices and a method thereof

(75) Inventors: Gyung-Su Byun, Seoul (KR); Min-Ho Park, Daejeon (KR); Hong-Beom Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/509,006

(22) Filed: Aug. 24, 2006

(30) Foreign Application Priority Data
Aug. 25, 2005 (KR) 10-2005-0078177

(51) Int. Cl. G11C 29/00; G11C 7/00

(52) U.S. Cl. 365/201

(57) ABSTRACT

A semiconductor memory device and a method thereof are provided. The example method may include determining whether a currently tested cell is defective and repairing the currently tested cell, if the currently tested cell is determined to be defective, before determining whether a next tested cell is defective. The example method may be performed by a semiconductor memory device including a built-in self-test (BIST) circuit and a repair control circuit. Alternatively, the example method may be performed by a semiconductor memory device including a BIST circuit, a repair control circuit and a storage device.

### PRIORITY STATEMENT

This application claims priority to Korean Patent Application No. 2005-78177 filed on Aug. 25, 2005 in the Korean Intellectual Property Office (KIPO), the contents of which are incorporated herein by reference in their entirety.

### BACKGROUND OF THE INVENTION

1. Field of the Invention

Example embodiments of the present invention relate generally to semiconductor memory devices and a method thereof, and more particularly to semiconductor memory devices and a method of testing a semiconductor memory device.

2. Description of the Related Art

Generally, a unit cell area of a conventional semiconductor memory device may be reduced to facilitate an increase in a storage capacity of the semiconductor memory device. A reduction of the unit cell area of the semiconductor memory device may decrease a capacitance of a cell capacitor. Due to the decrease in capacitance of the cell capacitor, electric charges stored in the cell capacitor may likewise be reduced. Thus, cell characteristics of the semiconductor memory device may be affected by a manufacturing process thereof. In addition, the cells of the semiconductor memory device may be densely arranged with respect to each other, which may increase interference among neighboring cells within the semiconductor memory device. The cells of the semiconductor memory device may be affected by noise in address lines and data lines.

A built-in self-test (BIST) circuit may be used to test conventional semiconductor memory devices having higher cell densities. A BIST circuit for performing a memory test may be included in the semiconductor memory device, and the semiconductor memory device may be tested through the BIST circuit.

FIG. 1 is a schematic block diagram illustrating a conventional memory test device.

Referring to FIG. 1, the conventional memory test device may include a tester 1 for detecting a defective cell and a semiconductor memory device 2. The semiconductor memory device 2 may include a BIST circuit 2a, a cell array 2b and a redundancy circuit 2c.

Referring to FIG. 1, the BIST circuit 2a, in response to a control signal from the tester 1, may generate test pattern data. The BIST circuit 2a may write the test pattern data into the cell array 2b, and may read the test data written from the cell array 2b. The BIST circuit 2a may compare the generated test pattern data with the read test data to determine whether or not the test cell is a defective cell. The BIST circuit 2a may provide a result of the test to the tester 1.

While not illustrated within the conventional BIST circuit 2a of FIG. 1, the BIST circuit 2a may include a pattern generator, an address generator and a comparator. The pattern generator may generate test pattern data in response to the control signal of the tester 1, may write the test pattern data into the cell array 2b, and may output the test pattern data to the comparator. The address generator may generate a test cell address, and may output the test cell address to the pattern generator and the comparator. The comparator may read the test data written in the cell array 2b and may compare the test pattern data with the read test data to provide the test result. The comparator may determine whether or not a tested device is defective by comparing the test pattern data from the pattern generator with the test data read from the cell array 2b, based on a test algorithm. If the comparator determines that the fail bit occurs in the cell, the BIST circuit 2a may store an address of the cell in which the fail bit occurs into an internal storage unit and/or may transfer the address to the tester 1.

Referring again to FIG. 1, after all the cells in the cell array 2b are tested, if the tester 1 determines that the tested chip includes a defect, the tester 1 may output a repair command if the tested chip is repairable, or alternatively may classify the tested chip as a defective die if the tested chip is not repairable. In response to the repair command, a repairable chip may replace a row or column including the defective cell with a row or column of a redundancy circuit by processing a fuse circuit in the redundancy circuit. Accordingly, the repairable chip may be repaired to function as a normal die.

As described above, a conventional memory test device may determine, for all the cells in the memory cell array, whether each cell is defective or not, and may store the addresses of all bits or cells determined to be defective as fail bits within a register. After the test is finished, the conventional memory test device may perform a repair process (e.g., if the chip is repairable) for the defective cells based on the addresses stored in the register. The conventional memory test device of FIG. 1 may be associated with relatively long testing times and relatively low efficiency because an interface circuit between the tester 1 and semiconductor memory device 2 may be relatively complex and an entirety of the semiconductor memory device 2 may typically be tested before any repairs may be made. Further, the conventional memory test device of FIG. 2 may require sufficient storage space for storing the test result.

### SUMMARY OF THE INVENTION

An example embodiment of the present invention is directed to a method of testing a semiconductor memory device, including determining whether a currently tested cell is defective and repairing the currently tested cell, if the currently tested cell is determined to be defective, before determining whether a next tested cell is defective.

Another example embodiment of the present invention is directed to a semiconductor memory device, including a built-in self-test (BIST) circuit configured to generate a fail signal if a defective cell is detected by scanning a cell array in response to a test start command from an external tester and a repair control circuit configured to store an address corresponding to a currently tested cell in response to a clock signal if the currently tested cell is determined to be defective, the repair control circuit further configured to replace the defective cell with a redundancy cell in a redundancy circuit before determining whether a next tested cell is defective.

Another example embodiment of the present invention is directed to a semiconductor memory device, including a built-in self-test (BIST) circuit configured to detect defective cells by scanning a cell array in response to a test start command from an external tester and configured to output a test result to the external tester after scanning the cell array, a storage unit configured to store addresses of the defective cells and a repair control circuit configured to receive a repair command from the external tester and configured to output a repair signal for connecting one of a plurality of redundancy circuits a defective cell associated with the defective cell address in response to the repair command.

Another example embodiment of the present invention is directed to a semiconductor memory device and method capable of reducing test time by repairing a defective cell after the defective cell is detected.

Another example embodiment of the present invention is directed to a semiconductor memory device and method capable of reducing a storage area for storing fail information.

### BRIEF DESCRIPTION OF THE DRAWINGS

The accompanying drawings are included to provide a further understanding of the invention, and are incorporated in and constitute a part of this specification. The drawings illustrate example embodiments of the present invention and, together with the description, serve to explain principles of the present invention.

FIG. 1 is a schematic block diagram illustrating a conventional memory test device.

FIG. 2 is a block diagram illustrating a memory test device according to an example embodiment of the present invention.

FIG. 3 is a block diagram illustrating a repair control circuit of the memory test device of FIG. 2 according to another example embodiment of the present invention.

FIG. 4 is a circuit diagram illustrates a latch circuit according to another example embodiment of the present invention.

FIG. 5 is a circuit diagram illustrating a fuse cut flip-flop according to another example embodiment of the present invention.

FIG. 6 is a circuit diagram illustrating a fuse circuit within a redundancy circuit according to another example embodiment of the present invention.

FIG. 7 is a timing diagram illustrating signal levels during a fuse cut process performed by the redundancy circuit of FIG. 6 according to another example embodiment of the present invention.

FIG. 8 is a timing diagram illustrating signal levels preceding a fuse cut process performed by the redundancy circuit of FIG. 6 according to another example embodiment of the present invention.

FIG. 9 is a timing diagram illustrating signal levels following a fuse cut process performed by the redundancy circuit 23 of FIG. 6 according to another example embodiment of the present invention.

FIG. 10 is a timing diagram illustrating an operation of the memory test device of FIG. 2 according to another example embodiment of the present invention.

FIG. 11 is a block diagram illustrating another memory test device according to another example embodiment of the present invention.

FIG. 12A is a block diagram illustrating a storage circuit including a plurality of latch circuits according to another example embodiment of the present invention.

FIG. 12B is a circuit diagram illustrating one of the plurality of latch circuits of the FIG. 12A according to another example embodiment of the present invention.

FIG. 13 is a block diagram illustrating a configuration of a redundancy circuit according to another example embodiment of the present invention.

FIG. 14A is a schematic diagram illustrating an electrical fuse circuit providing a master signal for indicating whether a fuse circuit is enabled or disabled according to another example embodiment of the present invention.

FIG. 14B is a circuit diagram illustrating an electrical fuse circuit according to another example embodiment of the present invention.

FIG. 14C is a circuit diagram illustrating a fuse circuit according to another example embodiment of the present invention.

### DETAILED DESCRIPTION OF EXAMPLE EMBODIMENTS OF THE PRESENT INVENTION

Example embodiments of the present invention are disclosed herein. However, specific structural and functional details disclosed herein are merely representative for purposes of describing example embodiments of the present invention. Example embodiments of this invention may, however, be embodied in many alternate forms and should not be construed as limited to example embodiments of the present invention set forth herein.

Accordingly, while example embodiments of the present invention may be susceptible to various modifications and alternative forms, specific example embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.)

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

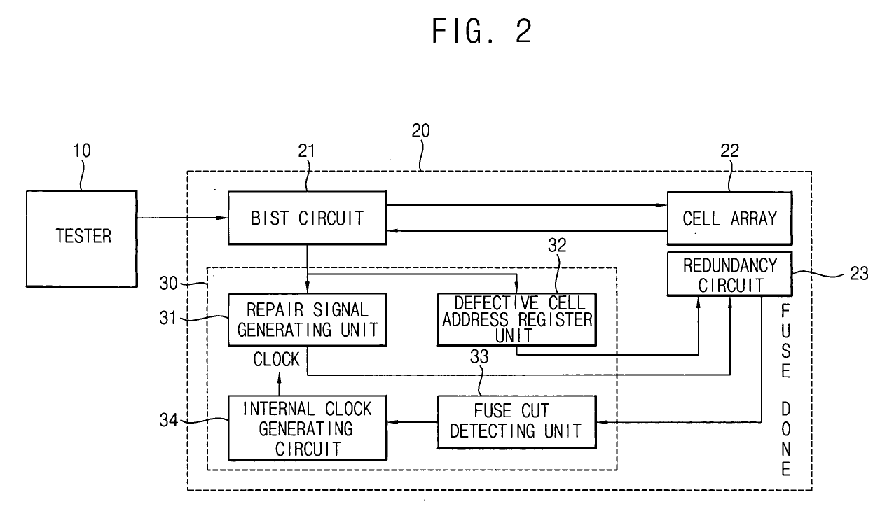

FIG. 2 is a block diagram illustrating a memory test device according to an example embodiment of the present invention.

In the example embodiment of FIG. 2, the memory test device may include a tester 10 and a semiconductor memory device 20. The semiconductor memory device 20 may include a built-in self-test (BIST) circuit 21, a cell array 22, a redundancy circuit 23, and a repair control circuit 30.

In the example embodiment of FIG. 2, the repair control circuit 30 may include a repair signal generating unit 31, a defective cell address register unit 32, a fuse cut detecting unit 33, and an internal clock generating circuit 34. The BIST circuit 21 may output a control signal to the repair signal generating unit 31 and the defective cell address register if a defective cell is detected. The repair signal generating unit 31 may output a repair enable signal in response to the control signal. A defective cell address may be stored in the defective cell address register 32 upon a detection of a defective cell. The defective cell address stored in the defective cell address register 32 may be transferred to the redundancy circuit 23. The redundancy circuit 23 may then repair the defective cell.

In the example embodiment of FIG. 2, if the repair process is performed by fuse cutting in the redundancy circuit 23, a fuse done signal, which may indicate when the repair process completes, may be transferred to a fuse cut detecting unit 33 from the redundancy circuit 23. The fuse cut detecting unit 33 may receive the fuse done signal and may transfer the fuse done signal to the internal clock generating circuit 34. The internal clock generating circuit 34 may adjust an internal clock in response to the fuse done signal from the fuse cut detecting unit 33.

It will be appreciated by one of ordinary skill in the art that the memory test device of the example embodiment of FIG. 2 may reduce test and repair times by replacing a defective cell with a redundancy cell in a redundancy circuit more rapidly following a detection of a defective cell during a memory test process (e.g., because all rows/columns of the semiconductor memory device need not be tested before replacing one or more columns/rows).

Hereinafter, portions of the semiconductor memory device 20 of the example embodiment of FIG. 2 will be described in greater detail with reference to the following figures.

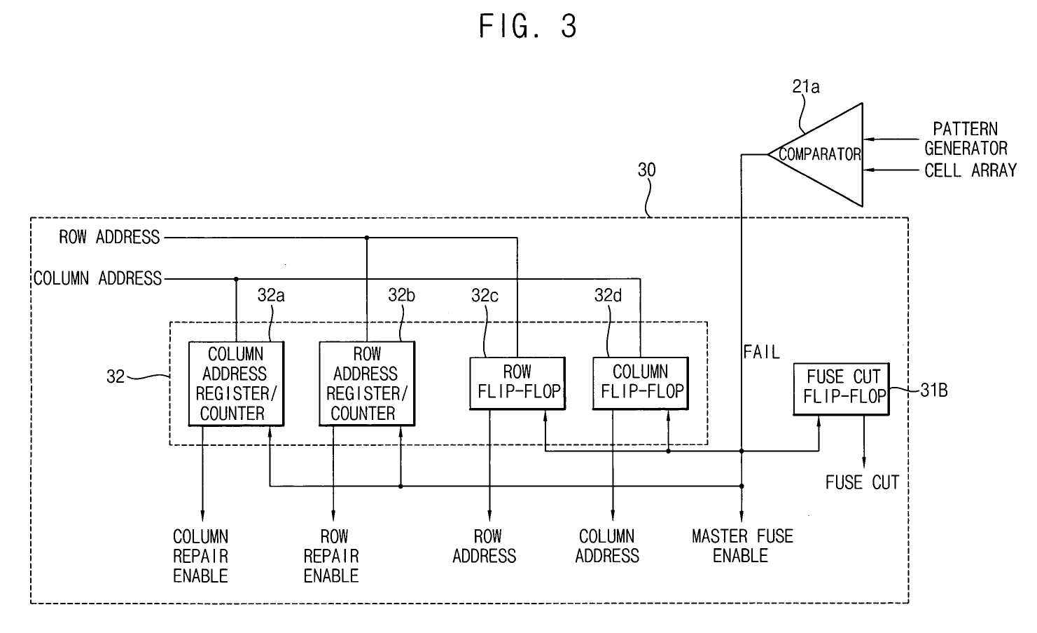

FIG. 3 is a block diagram illustrating the repair control circuit 30 of FIG. 2 according to another example embodiment of the present invention. In the example embodiment of FIG. 3, the repair control circuit 30 may include a fuse cut flip-flop 31B, a defective cell address register unit 32, a fuse cut detecting unit (not shown), and an internal clock generating circuit (not shown).

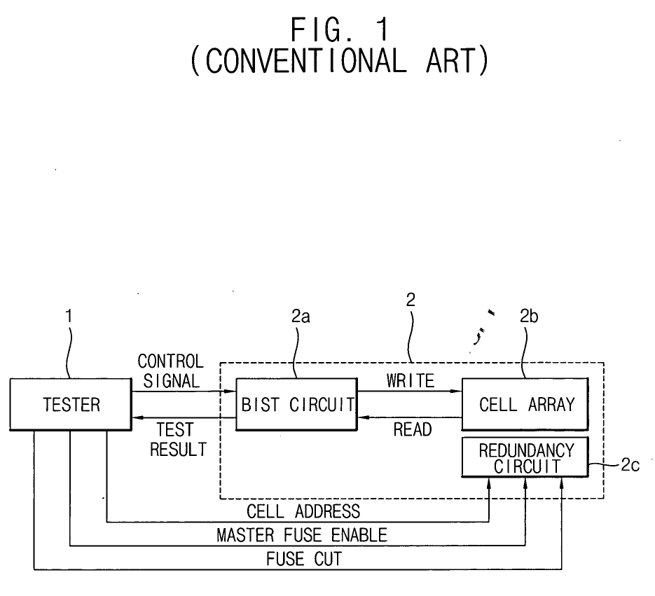

As described with respect to the conventional memory test device of FIG. 1, a comparator 21a of the BIST circuit 21 may compare test data read from a cell array 22 with test pattern data outputted from a pattern generator. If a defective cell is detected, the comparator 21a may output a fail signal.

Referring to the example embodiment of FIG. 3, the fuse cut flip-flop 31B and each block within the defective cell address register unit 32 may be enabled in response to the fail signal. In addition, the fail signal may be used as a master fuse enable signal for enabling the redundancy circuit 23. An address corresponding to a tested cell may be latched in a row flip-flop 32c and a column flip-flop 32d. The latched address may be provided to the redundancy circuit 23.

In the example embodiment of FIG. 3, a column address register/counter 32a and a row address register/counter 32b may store defective cell addresses, and may output a repair enable signal if a number of defective cell detections is less than or equal to a repair threshold (e.g., a number of times the redundancy circuit may be capable of cell repair). Alternatively, the column address register/counter 32a and the row address register/counter 32b may output a repair disable signal if the number of defective cell detections is greater than the repair threshold.

In the example embodiment of FIG. 3, a row flip-flop 32c and a column flip-flop 32d may include a plurality of bit latch circuits. In an example, a number of the bit latch circuits may correspond to a number of address bits.

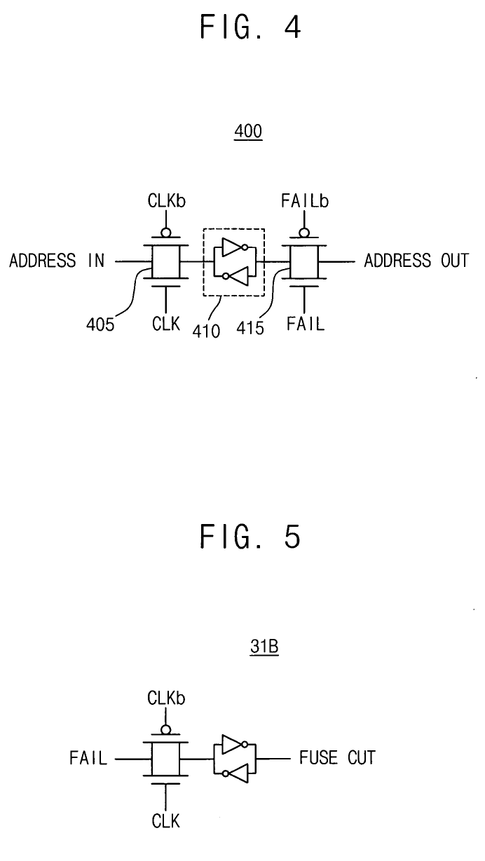

Hereinafter, a single bit latch circuit among the plurality of bit latch circuits will be described with reference to FIG. 4.

FIG. 4 is a circuit diagram illustrates a latch circuit 400 according to another example embodiment of the present invention. In an example, the bit latch 400 of FIG. 4 may be representative of one of the plurality of bit latch circuits included within the row flip-flop 32c and the column flip-flop 32d of FIG. 2.

In the example embodiment of FIG. 4, the latch circuit 400 may include an input switching unit 405, an output switching unit 415, and a latch unit 410. The input switching unit 405 may switch the address bit signal in response to a clock signal. The output switching unit 415 may output a latched bit signal in response to the fail signal. The latch unit 410 may latch an address bit signal received from the input switching unit. As illustrated in the example embodiment of FIG. 4, the input and output switching units 405/415 may be implemented with transfer gates.

FIG. 5 is a circuit diagram illustrating the fuse cut flip-flop 31B of FIG. 3 according to another example embodiment of the present invention.

In the example embodiment of FIG. 5, if the fuse cut flip-flop 31B receives a fail signal, the fuse cut flip-flop 31B may output a fuse cut signal by latching the fail signal in response to a clock signal. If the fuse cut signal is outputted from the fuse cut flip-flop 31B, a corresponding fuse circuit in the redundancy circuit 23 (not shown in FIG. 5) may cut a fuse coupled with the defective cell.

In the example embodiment of the present invention, because the fuse cutting may be performed by the redundancy circuit 23, an internal clock of the semiconductor memory device 20 may be adjusted based on an amount of time spent performing the fuse cutting operation. Accordingly, the internal clock generating unit 34 may adjust the internal clock cycle based on an external clock signal and a fuse done signal outputted from the fuse cut detecting unit 33.

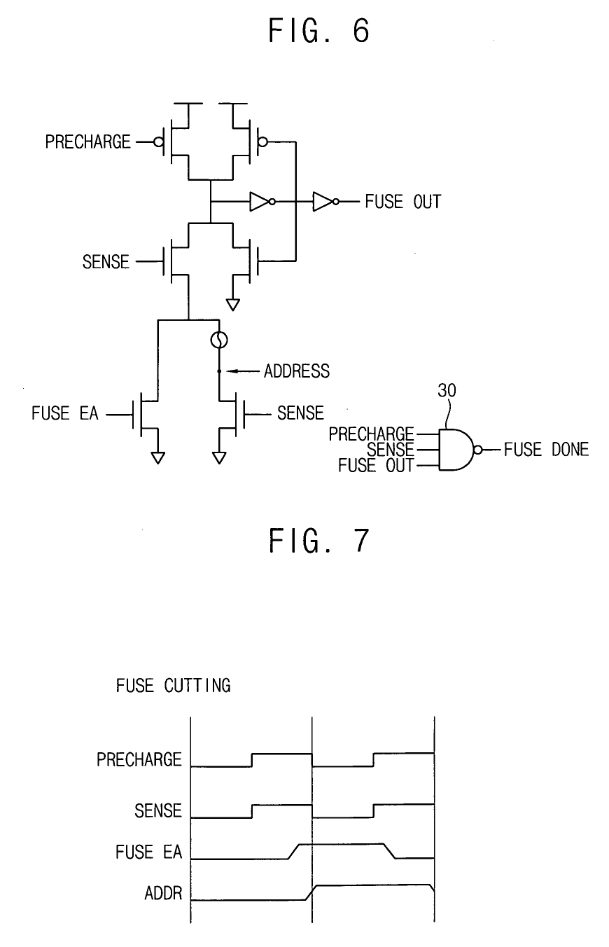

FIG. 6 is a circuit diagram illustrating a fuse circuit 600 within the redundancy circuit 23 according to another example embodiment of the present invention.

In the example embodiment of FIG. 6, the fuse circuit 600 may be an electrical fuse (e-fuse). In an example, a fuse done signal may be generated by the fuse cut detecting unit 33 after performing the fuse cut process.

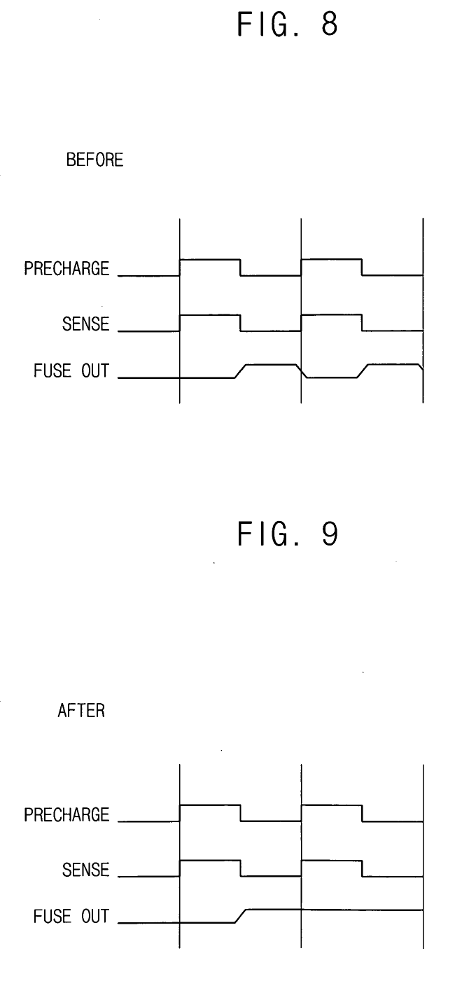

FIG. 7 is a timing diagram illustrating signal levels during a fuse cut process performed by the redundancy circuit 23 of FIG. 6 according to another example embodiment of the present invention. FIG. 8 is a timing diagram illustrating signal levels preceding a fuse cut process performed by the redundancy circuit 23 of FIG. 6 according to another example embodiment of the present invention. FIG. 9 is a timing diagram illustrating signal levels following a fuse cut process performed by the redundancy circuit 23 of FIG. 6 according to another example embodiment of the present invention.

In the example embodiments of FIGS. 6 through 8, a state of the fuse out signal may be determined based on a phase of a precharge signal and a sense signal, such that the fuse out signal may have an opposite phase with respect to the precharge signal and the sense signal before the fuse cut process. Therefore, a logic level (e.g., a first logic level such as a higher logic level or logic “1”, a second logic level such as a lower logic level or logic “0”, etc.) of the fuse done signal outputted from the fuse cut detecting unit 33 (e.g., an output signal of an AND gate) may be maintained at the second logic level (e.g., a lower logic level or logic “0”).

In the example embodiment of FIG. 9, after the fuse cut process, the fuse out signal may be maintained at the first logic level (e.g., a higher logic level or logic “1”) irrespective of the logic levels of the precharge signal and the sense signal. As a result, the output signal of the AND gate receiving the precharge, sense and fuse out signals may transition to the first logic level (e.g., a higher logic level or logic “1”) if the phase of a precharge spot and sense spot is set to the first logic level (e.g., a higher logic level or logic “1”). Accordingly, the fuse done signal may be obtained by using the AND gate to perform an AND operation on the precharge signal, the sense signal and the fuse out signal, with the AND output being the fuse done signal. Thus, the fuse done signal may be set to the first logic level (e.g., a higher logic level or logic “1”) if each of the precharge signal, the sense signal and the fuse out signal is set to the first logic level.

In the example embodiment of FIG. 6, a logic gate for obtaining the fuse done signal may be illustrated as a NAND gate. If a NAND gate is deployed, as shown in FIG. 6, the fuse cut process may be completed when the fuse done signal transitions to the second logic level (e.g., a lower logic level or logic “0”). In an alternative example, if an AND gate is employed instead of a NAND gate, the fuse cutting may be activated if the output signal of the AND gate is set to the first logic level (e.g., a higher logic level or logic “1”).

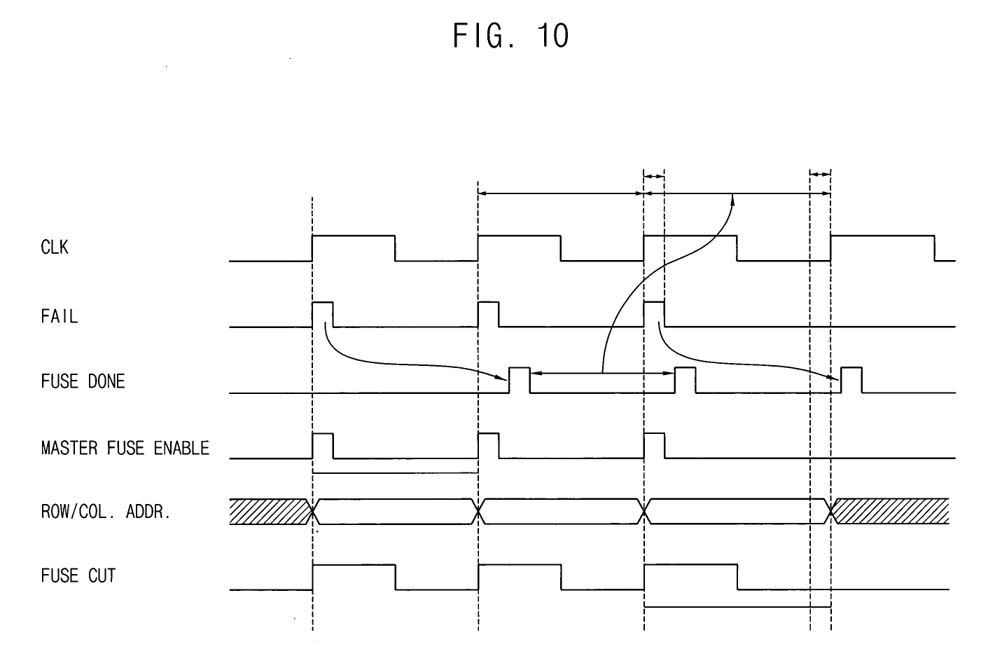

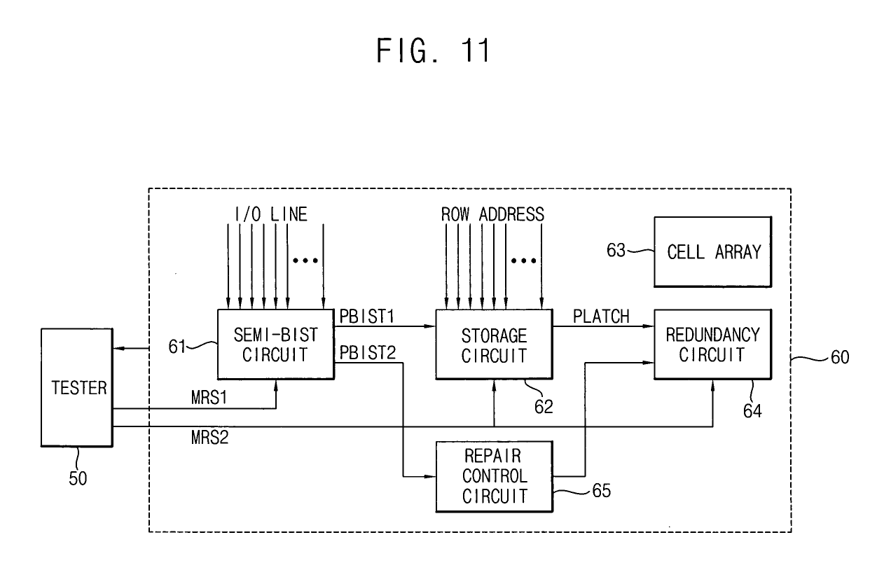

FIG. 10 is a timing diagram illustrating an operation of the memory test device of FIG. 2 according to another example embodiment of the present invention.

In the example embodiment of FIG. 10, the internal clock generating unit 34 may receive the fuse done signal as a feedback signal if the fuse cut process is completed. The internal clock generating unit 34 may adjust a clock cycle based on the fuse done signal. The internal clock generating unit 34 may adjust the clock cycle of an external clock based on an input timing of the fuse done signal to generate the internal clock signal. Further, if fail bits occur consecutively (e.g., in FIG. 10, three consecutive fail bits are shown), the master fuse enable signal and row/column address information may be transmitted to the fuse circuit of the redundancy circuit. In addition, the fuse cut signal for cutting the fuse may be outputted to the fuse circuit.

In the example embodiment of FIG. 10, after a fuse corresponding to a first defective cell is cut and the first fuse done signal is generated to indicate that the fuse cut process of the first defective cell is finished, a fuse corresponding to a second defective cell may be cut. If a duration of the fuse cut process is relatively low compared to the clock cycle, the clock cycle of the clock signal generated by the internal clock generating circuit 34 may be adjusted (e.g., lowered) in accordance with the fuse done signal. Likewise, if a duration of the fuse cut process is relatively high compared to the clock cycle, the clock cycle of the clock signal generated by the internal clock generating circuit 34 may be adjusted (e.g., increased) in accordance with the fuse done signal.

Returning to the example embodiment of FIG. 2, the semiconductor memory device 20 may determine, in the comparator 21a of the BIST circuit 21, whether or not a defective cell is detected, and may store the defective cell address in the defective cell address register 32. The semiconductor memory device 20 may output the fuse cut signal. The fuse cut signal may be transferred to the redundancy circuit 23 dynamically in response to a defected cell detection such that the semiconductor device 20 need not wait for all defective cells to be detected before performing a detected, defective portion. Further, if the number of the defective cells exceeds the number of times the redundancy circuit 23 may repair the defective cells, the chip may be considered to be unrepairable. Therefore, the unrepairable chips may be determined more rapidly than the conventional art. For example, if a redundancy circuit is capable of repairing 10 defective cells, and 50 defective cells are present on a given semiconductor memory device, a conventional fuse cut process may detect and store all 50 defective cell addresses and thereafter determine the semiconductor memory device to be unrepairable. In contrast, a fuse cut process according to example embodiments of the present invention may determine the semiconductor memory device having 50 defects to be unrepairable when the 11^{th} defect is detected (e.g., because the number of detected defects exceeds the number of possible repairs).

FIG. 11 is a block diagram illustrating another memory test device according to another example embodiment of the present invention. In the example embodiment of FIG. 11, it is understood the memory test may be implemented using a row and/or column address. However, for the sake of simplicity, the example embodiment of FIG. 11 has been illustrated and described below only with respect to a row address.

In the example embodiment of FIG. 11, the memory test device may include a semiconductor memory device 60 and an external tester 50. The semiconductor memory device 60 may include a semi-BIST circuit 61, a storage circuit 62, a repair control circuit 65, a cell array 63 and a redundancy circuit 64. A memory test of the semiconductor memory device 60 may be controlled by the external tester 50.

In the example embodiment of FIG. 11, the semi-BIST circuit 61 may transfer read and write data through respective data pins, and may compare the write data to a cell array with the read data from the cell array so as to determine whether or not a tested cell is defective. The storage circuit 62 may store an address corresponding to the defective cell outputted from the semi-BIST circuit 61. The repair control circuit 65 may output a repair enable signal if a defective cell is detected. The defective cell in the cell array 63 may be replaced with a redundancy cell in the redundancy circuit 64 based on the defective cell address stored in the storage circuit 62.

In the example embodiment of FIG. 11, the semiconductor memory device 60 may have, for example, a structure in which two word lines and one column selection line (CSL) may be enabled if a row address strobe (/RAS) signal is activated, such that a given number of bits (e.g., eight bits) may be outputted. In an example, first bits (e.g., 00 to 03) may be outputted through a first word line, and second bits (e.g., 04 to 07) may be outputted through a second word line. Accordingly, in an example, eight bits may be outputted for a given /RAS signal.

In the example embodiment of FIG. 11, a first mode register set signal MRS1 may be a signal for enabling the semi-BIST circuit 61. If the first mode register set signal MRS1 is enabled, the semi-BIST circuit 61 may determine whether or not a tested cell is defective. A second mode register set signal MRS2 may be a signal for enabling a cutting of a fuse circuit in the redundancy circuit 64. After a memory test is finished, a fuse corresponding to the defective cell may be cut if the second mode register set MRS2 is enabled.

In the example embodiment of FIG. 11, the semi-BIST circuit 61 may detect a defective cell without an additional comparator. The storage circuit 62 may include a plurality of latch circuits (e.g., see FIG. 3), a number of which may correspond to a number of address bits.

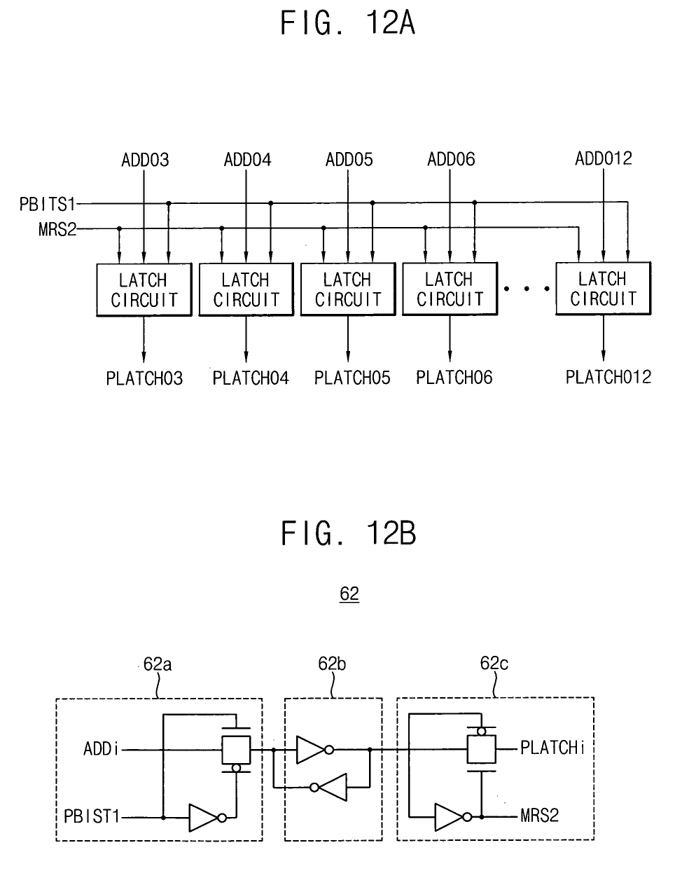

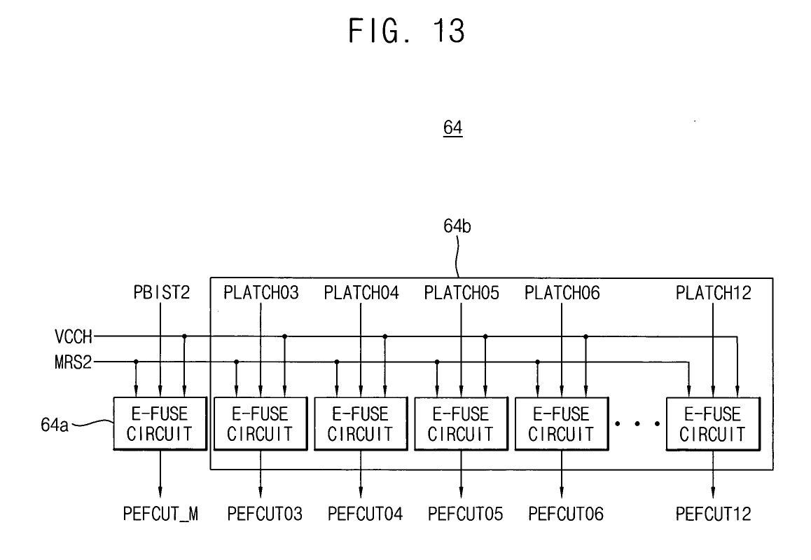

FIG. 12A is a block diagram illustrating a storage circuit including a plurality of latch circuits according to another example embodiment of the present invention.

In the example embodiment of FIG. 12A, for example, if eight bits of the defective cell address are sufficient to identify a position of the defective cell, the storage circuit may include eight latch circuits. If a plurality of the storage circuits are included, an equal number of defective cell addresses may be stored therein. In another example, a number of the storage circuits may be determined based on a number of redundancy circuits per bank. Although the defective cell addresses may be stored in the storage circuit, a number of repairable cells may be limited by the repair threshold (e.g., a number of times a given redundancy circuit may repair a cell).

FIG. 12B is a circuit diagram illustrating one of the plurality of latch circuits of the FIG. 12A according to another example embodiment of the present invention.

In the example embodiments of FIG. 12B, the latch circuit may include an input switching unit 62a, an output switching unit 62c, and a latch unit 62b. The input switching unit 62a may switch an address bit signal in response to a clock signal. The output switching unit 62c may output a latched bit signal in response to the second mode register set signal MRS2. The latch unit 62b may be coupled between the input switching unit 62a and the output switching unit 62c.

In the example embodiment of FIG. 12B, the input switching unit 62a may be activated if the first fail detection signal PBIST1 is set to the first logic level (e.g., a higher logic level or logic “1”). An address bit may be transferred to the latch unit 62b if the first fail detection signal PBIST1 is set to the first logic level. The transferred address bit may be stored in the latch unit 62b. The output switching unit 62c may be activated if the second mode register set signal MRS2 is set to the first logic level, and the latched address bit PLATCHi may be transferred to the redundancy circuit 64 to replace the defective cell corresponding to the latched address with a redundancy cell of the redundancy circuit 64.

FIG. 13 is a block diagram illustrating a configuration of the redundancy circuit 64 of FIG. 11 according to another example embodiment of the present invention.

In the example embodiment of FIG. 13, the redundancy circuit 64 may be configured based on an expected failure rate or integrity of a given chip. Generally, if more redundancy circuits are included, a yield of the semiconductor memory devices may be increased. However, excessive redundancy circuits result may decrease a memory capacity and increase a chip size.

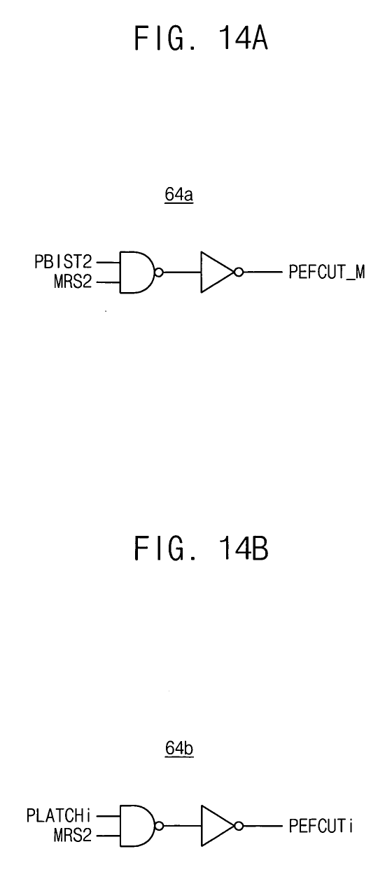

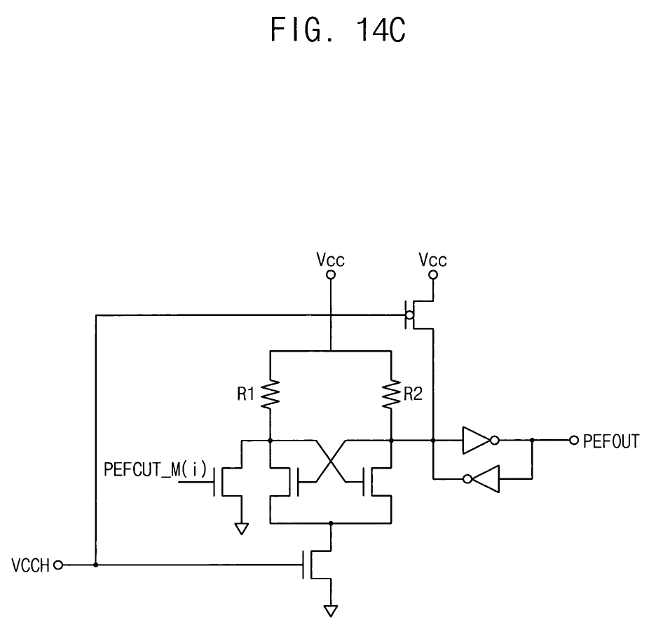

FIG. 14A is a schematic diagram illustrating an electrical fuse circuit 64a providing a master signal PEFCUT_M for indicating whether a fuse circuit is enabled or disabled according to another example embodiment of the present invention.

In the example embodiment of FIG. 14A, the electrical fuse circuit 64a may outputs the master signal PEFCUT_M of in response to the second mode register set signal MRS2 for an e-fuse cutting and the second fail detect signal PBIST2 for indicating whether or not a defective cell is detected.

FIG. 14B is a circuit diagram illustrating an electrical fuse circuit 64b according to another example embodiment of the present invention.

In the example embodiment of FIG. 14B, the electrical fuse circuit 64b may transfer an address signal PEFCUTi based on the second mode register set signal MRS2 for an e-fuse cutting and the latched address bit PLATCHi.

FIG. 14C is a circuit diagram illustrating a fuse circuit according to another example embodiment of the present invention.

In the example embodiment of FIG. 14C, the fuse circuit may be activated if the master signal PEFCUT_M(i) is set to the first logic level (e.g., a higher logic level or logic “1”), and the fuse circuit may operate in response to an enable signal of an address stored in a latch. The fuse circuit of FIG. 14C may be configured to perform a fuse cutting process.

Example operation of the memory test device of FIG. 11 and the components included therein illustrated in and described above with respect to FIGS. 12 through 14C will now be described in greater detail.

In example operation of the memory test device of FIGS. 11 through 14C, the semi-BIST circuit 61 may be activated by the first mode register set signal MRS1. For example, if the first mode register set signal MRS1 is set to the first logic level (e.g., a higher logic level or logic “1”), the semi-BIST circuit 61 may be enabled. The semi-BIST circuit 61 may transition the first fail detection signal PBIST1 to the second logic level (e.g., a lower logic level or logic “0”) if a tested cell is a normal or non-defective cell, and may transition the first fail detection signal PBIST1 to the first logic level (e.g., a higher logic level or logic “1”) if a tested cell is a defective cell. The semi-BIST circuit 61 may transition the second fail detection signal PBIST2 to the first logic level if at least one defective cell is detected, and may transition the second fail detection signal PBIST2 to the second logic level if no defective cells are detected.

In example operation of the memory test device of FIGS. 11 through 14C, the first fail detection signal PBIST1 may be outputted a single time for each tested cell, and the second fail detection signal PBIST2 may be outputted once for each read cycle (e.g., for eight cells).

In example operation of the memory test device of FIGS. 11 through 14C, if a defective cell is detected, the first fail detection signal PBIST1 may be outputted at the first logic level. The first logic level may be applied to the latch circuit, and an address of the defective cell may be stored in the latch circuit. If more than two defective cells are detected, an address of the last or most recent defective cell may be stored in the latch circuit. If a defective cell is not detected, the first fail detection signal PBIST1 may be outputted at the second logic level, and the latch circuit may be disabled.

In example operation of the memory test device of FIGS. 11 through 14C, if the second fail detection signal PBIST2 is set to the first logic level after the test for one cycle is finished, the first logic level of the second fail detection signal PBIST2 may indicate that at least one defective cell is detected, and that the last or most recently detected defective cell address may be stored in the latch circuit.

In example operation of the memory test device of FIGS. 11 through 14C, if the number of the latch circuits is two, two addresses corresponding to the two defective cells may be stored in the latch circuits, respectively. In an example, a first detected defective cell address may be stored in a first latch circuit, and a second detected defective cell address may be stored in a second latch circuit. It will be appreciated that the number of latch circuits and stored addresses may scale to any number (e.g., based on a number of expected defects in a tested semiconductor memory device).

In example operation of the memory test device of FIGS. 11 through 14C, if the second mode register set signal MRS2 is enabled, the address and fail information of the defective cell may be applied to the redundancy circuit. The redundancy circuit may then repair the defective cell. In an example, the second mode register set signal MRS2 may be set so that the repair process may be automatically processed after the test is terminated. Alternatively, the second mode register set signal MRS2 may be set so that the second mode register set signal MRS2 may be enabled if the second fail detection signal PBIST2 is set to the first logic level.

In another example embodiment of the present invention, a semiconductor memory device may be capable of comparing whether a defective cell is detected using a semi-BIST circuit without a register storing information of the defective cell. In addition, the defective cell address may be latched based on an output of the semi-BIST circuit. By latching an address of the defect, the defect may be repaired based on the MRS2 signal. Accordingly, a number of test and repair iterations and/or durations may be reduced by replacing a defective cell with a redundancy cell in a redundancy circuit “instantly” (e.g., without waiting for, and storing, results of a test of all cells within a tested semiconductor memory device) during a test process. Further, a chip size may be reduced because the semiconductor memory device need not include higher-capacity memory for storing defective cell addresses.

Example embodiments of the present invention being thus described, it will be obvious that the same may be varied in many ways. For example, it is understood that the above-described first and second logic levels may correspond to a higher level and a lower logic level, respectively, in an example embodiment of the present invention. Alternatively, the first and second logic levels/states may correspond to the lower logic level and the higher logic level, respectively, in other example embodiments of the present invention

Such variations are not to be regarded as a departure from the spirit and scope of example embodiments of the present invention, and all such modifications as would be obvious to one skilled in the art are intended to be included within the scope of the following claims.

What is claimed is:

1. A method of testing a semiconductor memory device, comprising:
determining whether a currently tested cell is defective; and
repairing the currently tested cell, if the currently tested cell is determined to be defective, before determining whether a next tested cell is defective.

2. The method of claim 1, further comprising:
receiving a test start command from an external tester; and
storing an address of the currently tested cell in response to a clock signal,
wherein the determining and repairing are performed during a testing of each of a plurality of cells within a cell array of the semiconductor memory device in response to the test start signal, the plurality of cells including the currently and next tested cells, the testing including determining whether the currently tested cell is defective and repairing the currently tested cell before testing the next tested cell is tested if the currently tested cell is determined to be defective.

3. The method of claim 2, further comprising:
counting a defect number indicating a number of currently tested cells which are determined to be defective;
outputting a repair enable signal if the defect number is less than or equal to a repair threshold, the repair enable signal indicating to repair a defect and the repair threshold being a number of defects a redundancy circuit is capable of repairing; and
outputting a repair disable signal if the defect number is greater than the repair threshold.

4. The method of claim 3, wherein the semiconductor memory device is determined to be defective if the repair disable signal is output.

5. The method of claim 1, further comprising:
generating a fuse done signal after the currently tested cell is repaired, the fuse done signal a completion of the repairing; and
adjusting a clock cycle in response to the fuse done signal.

6. The method of claim 1, further comprising:
receiving a test start command from an external tester;
reporting a test result to the external tester after all cells are tested for defects;
receiving a repair command from the external tester; and
connecting a redundancy circuit to the defective cell address in response to the repair command,
wherein the address of each cell determined to be defective is stored in a first in, first out (FIFO) manner.

7. The method of claim 6, wherein the test start command and the repair command correspond to mode register set commands.

8. The method of claim 6, wherein a number of the addresses stored in the FIFO manner is less than or equal to a number of redundancy circuits.

9. A semiconductor memory device, comprising:
a built-in self-test (BIST) circuit configured to generate a fail signal if a defective cell is detected by scanning a cell array in response to a test start command from an external tester; and
a repair control circuit configured to store an address corresponding to a currently tested cell in response to a clock signal if the currently tested cell is determined to be defective, the repair control circuit further configured to replace the defective cell with a redundancy cell in a redundancy circuit before determining whether a next tested cell is defective.

10. The semiconductor memory device of claim 9, wherein the repair control circuit includes:
a register unit configured to output a repair master signal to the redundancy circuit if the currently tested cell is determined to be defective, configured to store the address corresponding to the currently tested cell in response to a clock signal, and configured to output a defective cell address of the currently tested cell;
a repair enable signal generating unit configured to outputting a repair enable signal if a defect number is less than or equal to a repair threshold, the repair enable signal indicating to repair a defect, the defect number indicating a counted number of defects detected in the semiconductor memory device and the repair threshold being a number of defects the redundancy circuit is capable of repairing and outputting a repair disable signal if the defect number is greater than the repair threshold.
a fuse-cut signal generating unit configured to latch the defective cell address in response to the clock signal and configured to output a fuse-cut signal to a cell associated with the defective cell address.

11. The semiconductor memory device of claim 10, wherein the repair control circuit further includes:
a fuse-cut detecting unit configured to generate a fuse done signal after the redundancy circuit repairs the defective cell address; and
a clock generating unit configured to adjust a cycle of the clock in response to the fuse done signal.

12. The semiconductor memory device of claim 10, wherein the register unit includes a plurality of latch circuits corresponding to a number of address bits, wherein each of the latch circuits includes:
an input switching unit configured to switch an address bit signal in response to the clock signal;
an output switching unit configured to output a latched bit signal in response to the fail signal; and
a latch unit coupled between the input switching unit and the output switching unit.

13. A semiconductor memory device, comprising:
a built-in self-test (BIST) circuit configured to detect defective cells by scanning a cell array in response to a test start command from an external tester and configured to output a test result to the external tester after scanning the cell array;
a storage unit configured to store addresses of the defective cells; and
a repair control circuit configured to receive a repair command from the external tester and configured to output a repair signal for connecting one of a plurality of redundancy circuits a defective cell associated with the defective cell address in response to the repair command.

14. The semiconductor memory device of claim 13, wherein the storage unit is configured to store the addresses in a first in, first out (FIFO) manner.

15. The semiconductor memory device of claim 13, wherein the test start command and the repair command are mode register set commands.

16. The semiconductor memory device of claim 13, wherein the storage unit is configured to store a number of addresses being less than or equal to a number of the plurality of redundancy circuits.

17. The semiconductor memory device of claim 15, wherein the storage unit includes a plurality of latch circuits corresponding to a number of address bits, wherein each of the latch circuits includes:
an input switching unit configured to switch an address bit signal in response to a fail signal from the BIST circuit;
an output switching unit configured to output a latched bit signal in response to the repair command; and
a latch unit coupled between the input switching unit and the output switching unit.

18. The semiconductor memory device of claim 13, wherein the repair control circuit further includes:
a master repair signal generating unit configured to output a master repair signal in response to a fail signal and the repair command;
an address repair signal generating unit configured to output an address repair signal in response to a defective cell address stored in the storage unit and the repair command;
a master fuse signal generating unit configured to output a master fuse signal in response to the repair command; and
an address fuse signal generating unit configured to output an address fuse signal in response to the repair command.

19. A method of testing the semiconductor memory device of claim 9.

20. A method of testing the semiconductor memory device of claim 13.
